(19) United States
(12) Patent Application Publication
(10) Pub. No.: US 2025/0164872 A1
(43) Pub. Date: May 22, 2025

(54) SEMICONDUCTOR STRUCTURE INSPECTION METHOD, EXTREME ULTRAVIOLET (EUV) MASK INSPECTION METHOD, AND EUV LITHOGRAPHY METHOD

(71) Applicant: SAMSUNG ELECTRONICS CO., LTD., Suwon-si (KR)

(72) Inventors: Jiho PARK, Suwon-si (KR); Hun KIM, Suwon-si (KR); Sora PARK, Suwon-si (KR); Hyungkeun YOO, Suwon-si (KR); Younghun KWON, Suwon-si (KR); Jongchul KIM, Suwon-si (KR); Jaeyoung YANG, Suwon-si (KR); Chihoon LEE, Suwon-si (KR)

(73) Assignee: SAMSUNG ELECTRONICS CO., LTD., Suwon-si (KR)

(21) Appl. No.: 18/774,118

(22) Filed: Jul. 16, 2024

(30) Foreign Application Priority Data
Nov. 20, 2023 (KR) 10-2023-0161443

(51) Int. Cl. G03F 1/84; G03F 7/20; G06T 7/00; G06T 7/60

(52) U.S. Cl. CPC G03F 1/84; G03F 7/2002; G06T 7/0004; G06T 7/60; G06T 2207/20212; G06T 2207/30148

(57) ABSTRACT

A semiconductor structure inspection method includes obtaining an image of a semiconductor structure, the semiconductor structure including a wafer, a semiconductor layer, and an inspection pattern, determining a material of an insertion layer to be inserted in the semiconductor structure, determining a thickness of the insertion layer, inserting the insertion layer having the determined material and the determined thickness in the semiconductor structure, and measuring the semiconductor structure having the insertion layer inserted therein.

### CROSS-REFERENCE TO RELATED APPLICATION

This application is based on and claims priority under 35 U.S.C. § 119 to Korean Patent Application No. 10-2023-0161443, filed on Nov. 20, 2023, in the Korean Intellectual Property Office, the disclosure of which is incorporated by reference herein in its entirety.

### BACKGROUND

Example embodiments of the disclosure relate to a semiconductor structure inspection method, an extreme ultraviolet (EUV) mask inspection method, and an EUV lithography method. More particularly, example embodiments of the disclosure relate to a semiconductor structure inspection method, an EUV mask inspection method, and an EUV lithography method, which may all performed by inserting an insertion layer in a semiconductor structure.

Semiconductor structures may formed using a variety of semiconductor manufacturing processes, including deposition, ion implantation, photolithography, and etching. As semiconductor structures have become more highly integrated, line widths of patterns included in the semiconductor structures have decreased and aspect ratios of the patterns have increased. Due to this decrease in line width and/or increase in aspect ratio, the level of difficulty of semiconductor fabrication processes, particularly in a lithography process, has increased.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor structure inspection method, an extreme ultraviolet (EUV) mask inspection method, and an EUV lithography method with enhanced reliability.

Additional aspects will be set forth in part in the description which follows and, in part, will be apparent from the description, or may be learned by practice of the presented embodiments.

According to an aspect of an example embodiment, a semiconductor structure inspection method may include obtaining an image of a semiconductor structure, the semiconductor structure including a wafer, a semiconductor layer, and an inspection pattern, determining a material of an insertion layer to be inserted in the semiconductor structure, determining a thickness of the insertion layer, inserting the insertion layer having the determined material and the determined thickness in the semiconductor structure, and measuring the semiconductor structure having the insertion layer inserted therein.

According to an aspect of an example embodiment, an EUV mask inspection method may include forming a photoresist layer on a wafer and a semiconductor layer of a semiconductor structure, forming a photoresist pattern by exposing the photoresist layer using an EUV mask, obtaining an image of the photoresist pattern, determining a material of an insertion layer to be inserted in the semiconductor structure, determining a thickness of the insertion layer, inserting the insertion layer in the semiconductor structure, and determining whether the EUV mask is defective by measuring the photoresist pattern with the insertion layer having the determined material and the determined thickness inserted in the semiconductor structure.

According to an aspect of an example embodiment, an EUV lithography method may include providing a semiconductor layer on a wafer, providing a photoresist layer on the wafer, exposing the photoresist layer on the wafer using an EUV mask, forming a photoresist pattern by developing the exposed photoresist layer, and determining whether the EUV mask is defective by inspecting the photoresist pattern, where the inspecting of the photoresist pattern may include obtaining an image of the photoresist pattern, determining a material of an insertion layer to be inserted in a semiconductor structure, the semiconductor structure including the semiconductor layer, the wafer, and the photoresist layer, determining a thickness of the insertion layer, inserting the insertion layer having the determined material and the determined thickness into the semiconductor structure, and measuring the photoresist pattern while the insertion layer is inserted in the semiconductor structure.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a flowchart illustrating a semiconductor structure inspection method according to one or more example embodiments;

FIG. 2 is a cross-sectional view illustrating a semiconductor structure according to one or more example embodiments;

FIG. 3 is a cross-sectional view illustrating a semiconductor structure according to one or more example embodiments;

FIG. 4 is a diagram illustrating a device for measuring an insertion layer, according to one or more example embodiments;

FIG. 5 is a cross-sectional view illustrating a sample including an insertion layer, according to one or more example embodiments;

FIG. 6 is a flowchart illustrating a method of selecting a thickness of an insertion layer, according to one or more example embodiments;

FIG. 7 is a diagram illustrating patch images obtained at a plurality of wavelengths, according to one or more example embodiments;

FIG. 8 is a diagram illustrating a method of combining a plurality of patch images, according to one or more example embodiments;

FIG. 9 is a diagram illustrating a method of determining a signal-to-noise ratio (SNR), according to one or more example embodiments;

FIGS. 10 to 12 are diagrams illustrating scanning electrode microscope (SEM) images of semiconductor structures including defects, according to one or more example embodiments;

FIG. 13 is a graph illustrating an SNR in a first condition and an SNR in a second condition, according to one or more example embodiments;

FIG. 14 is a block diagram illustrating a semiconductor structure inspection apparatus according to one or more example embodiments;

FIG. 15 is a block diagram illustrating a system for performing various processes according to one or more example embodiments; and

FIG. 16 is a flowchart illustrating an extreme ultraviolet (EUV) lithography method according to one or more example embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

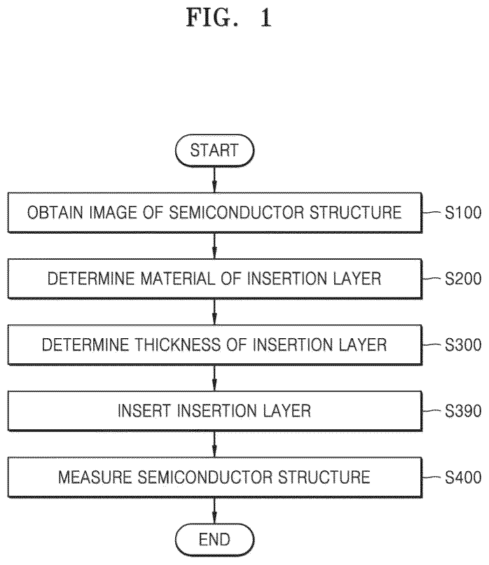

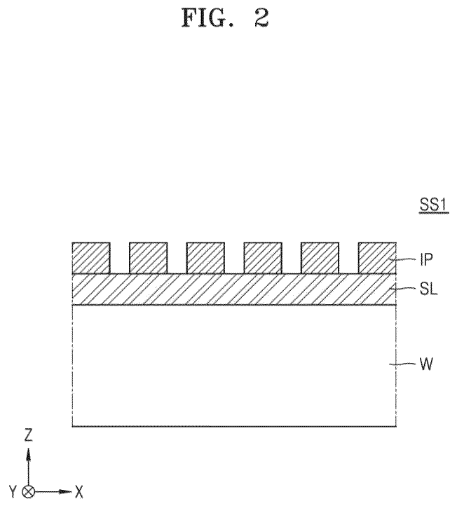

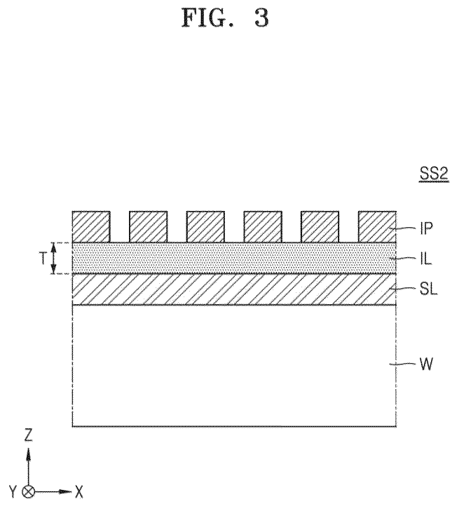

FIG. 1 is a flowchart illustrating a semiconductor structure inspection method according to one or more example embodiments. FIG. 2 is a cross-sectional view illustrating a semiconductor structure according to one or more example embodiments. FIG. 3 is a cross-sectional view illustrating a semiconductor structure according to one or more example embodiments. In one or more embodiments of the disclosure, a semiconductor structure may be measured to inspect the semiconductor structure or a mask used in the fabrication of the semiconductor structure.

As shown in FIG. 2, the semiconductor structure SS1 may not include an insertion layer IL. As shown in FIG. 3, the semiconductor structure SS2 may include the insertion layer IL. To perform inspection on a semiconductor structure, a semiconductor structure including an insertion layer IL (e.g., the structure SS2) may be inspected. In order to distinguish between the two semiconductor structures (i.e., between the semiconductor structure SS1 and the semiconductor structure SS2), the semiconductor structure before the insertion layer IL is inserted (FIG. 2) may be referred to as a first semiconductor structure SS1, and the semiconductor structure after the insertion layer IL is inserted (FIG. 3) may be referred to as a second semiconductor structure SS2.

Referring to FIG. 2, the first semiconductor structure SS1 may include a wafer W, a semiconductor layer SL, and an inspection pattern IP. The inspection pattern IP may refer to a pattern that is to be inspected as is described in detail below. Referring to FIG. 3, to inspect the inspection pattern IP, an insertion layer IL may be inserted between the inspection pattern IP and the wafer W, as shown in the second semiconductor structure SS2 of FIG. 3. For example, the insertion layer IL may be inserted between the inspection pattern IP and the semiconductor layer SL. In one or more embodiments, the insertion layer IL may be inserted between the semiconductor layer SL and the wafer W.

The wafer W may be formed as a semiconductor substrate. In one or more embodiments, the wafer W may be formed of a semiconductor such as silicon (Si) or germanium (Ge). In one or more embodiments, the wafer W may include a compound semiconductor such as silicon germanium (SiGe), silicon carbide (SiC), gallium arsenide (GaAs), indium arsenide (InAs), or indium phosphide (InP). The wafer W may include a conductive region, such as a well doped with impurities or a structure doped with impurities. In addition, the wafer W may have a device isolation structure such as a shallow trench isolation (STI) structure.

The semiconductor layer SL may include a semiconductor device formed on the wafer W. The semiconductor structure may further include a hard mask layer and/or a bonding layer for applying photoresist on the semiconductor layer SL.

The inspection pattern IP may include various types of patterns. For example, the inspection pattern IP may include a semiconductor pattern. A measurement device may inspect the inspection pattern IP to determine whether the inspection pattern IP is defective. In addition, when the inspection pattern IP includes a photoresist pattern, the measurement device may inspect the photoresist pattern to determine whether an extreme ultraviolet (EUV) mask is defective.

While FIGS. 2 and 3 illustrate a case where the inspection pattern IP is provided at a top portion of the semiconductor structure SS1/SS2, the disclosure is not limited thereto. For example, the inspection pattern IP may be provided at a bottom portion of the semiconductor structure SS1/SS2.

A method of inspecting a semiconductor structure SS1/SS2 by using the insertion layer IL is described in detail below.

Referring to the flowchart of FIG. 1, in operation S100 an image of the semiconductor structure may be obtained. The physical and/or chemical properties of the semiconductor structure may be measured by the measurement device. For example, a transmission electron microscope (TEM) may obtain an image of the semiconductor structure by measuring the semiconductor structure. However, the measurement device for measuring the semiconductor structure is not limited thereto, and various types of measurement devices may be used. The semiconductor structure may be modeled based on the obtained image of the semiconductor structure. That is, the semiconductor structure may be modeled by measuring dimensions of the semiconductor structure. For example, the semiconductor structure may be modeled by measuring the height, thickness, and/or width of the semiconductor structure. Measuring the semiconductor structure in operation S100 may be performed prior to operation S400 of measuring the semiconductor structure. That is, measurement of the semiconductor structure in operation S100 may be referred to as first measurement, and measurement of the semiconductor structure in operation S400 may be referred to as second measurement. The first measurement may be a preliminary measurement for the second measurement. In addition, in operation S100, the first semiconductor structure SS1 not including the insertion layer IL may be measured, and in operation S400, the second semiconductor structure SS2 including the insertion layer IL may be measured.

The semiconductor structure may be measured at a plurality of wavelengths. Bands of the plurality of wavelengths may be selected according to a size of an object to be inspected, a location of the object, and/or a surrounding material adjacent to the object. For example, the smaller the object to be inspected, the shorter the inspection wavelength. Furthermore, the higher the object to be inspected is located in the semiconductor structure, the shorter the inspection wavelength. Furthermore, a wavelength at which there is a large difference between refractive index values of the object to be inspected and a material adjacent to the object to be inspected may be selected as the inspection wavelength. For example, a wavelength band may be between about 150 nanometers (nm) to about 600 nm. In addition, the inspection wavelength may be selected in a wavelength band that slightly affects the semiconductor layer SL and the inspection pattern IP.

Subsequently, a material of the insertion layer IL to be used for the measurement of the semiconductor structure may be determined in operation S200. That is, the material of the insertion layer IL may be determined empirically and/or selected from a preconfigured list of selectable materials.

In order for the measurement device to easily measure the semiconductor structure in operation S400, the insertion layer IL may be inserted into the semiconductor structure in operation S390. Operation S390 of inserting the insertion layer IL may be performed after operations S200 and S300, although in one or more embodiments, operations S200 and/or S300 may be omitted, for example, when the properties of the insertion layer IL have been previously determined, such that the insertion layer IL may be inserted after operation S100. Operation S300 will be described in detail below, and the order of operations S100, S200, S300, S390 and S400 are not necessarily limited to the order as shown in FIG. 1.

The insertion layer IL may be inserted between the wafer W and a measurement target of the semiconductor structure. For example, the measurement target may include the inspection pattern IP. As the insertion layer IL is inserted between the measurement target of the semiconductor structure and the wafer W, the measurement device may easily measure the semiconductor structure. For example, as the insertion layer IL is inserted between the measurement target of the semiconductor structure and the wafer W, an optical signal reflected from the semiconductor structure may be amplified.

A material of the insertion layer IL may be determined based on a refractive index and an absorption coefficient of the insertion layer IL. According to one or more embodiments, a material with a high refractive index may be determined as the material of the insertion layer IL. According to one or more embodiments, the material of the insertion layer IL may be determined based on the difference between a refractive index of the inspection pattern IP and the refractive index of the insertion layer IL. In one or more embodiments, a material having a large difference between the refractive index of the inspection pattern IP and the refractive index of the insertion layer IL may be determined as the material of the insertion layer IL. In one or more embodiments, a material having a small difference between the refractive index of the inspection pattern IP and the refractive index of the insertion layer IL may be determined as the material of the insertion layer IL. In addition, a material with a low absorption coefficient may be determined as the material for the insertion layer IL.

The insertion layer IL may include an insulating material, a metal, a metal oxide, and/or a metal nitride. For example, the insertion layer IL may include silicon oxide (SiOₓ), silicon nitride (SiNₓ), SiN, silicon oxynitride (SiON), titanium nitride (TiN), tungsten (W), gold (Au), photoresist PR, silicon oxycarbide (SiOC), and/or SiC. Furthermore, a material having high adhesion properties with respect to layers overlying and underlying the insertion layer IL may be determined as the material of the insertion layer IL. In addition, a material that is less affected by a semiconductor fabrication process may be determined as the material of the insertion layer IL.

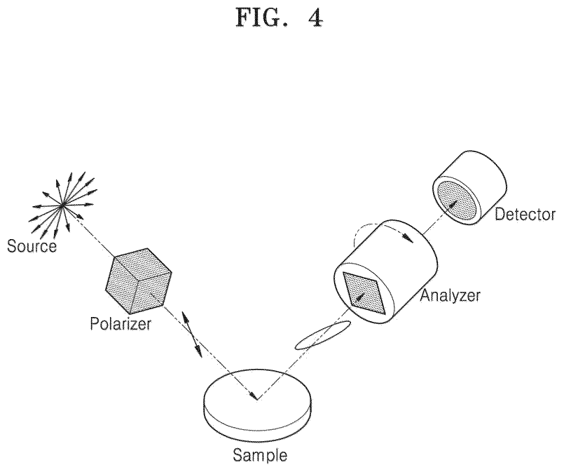

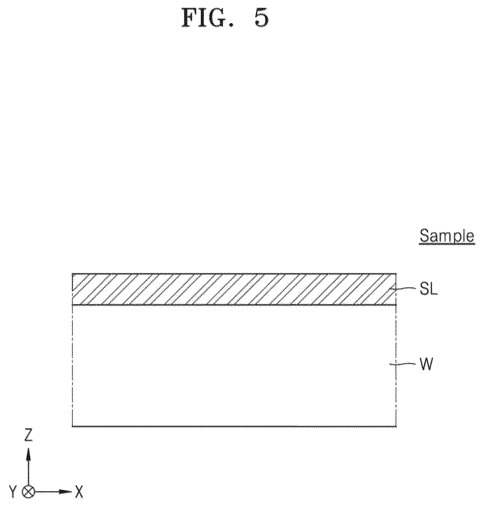

The process of measuring the refractive index and absorption coefficient of the insertion layer IL is described with reference to FIGS. 4 and 5.

FIG. 4 is a diagram illustrating a device for measuring an insertion layer, according to one or more example embodiments. FIG. 5 is a cross-sectional view illustrating a sample including an insertion layer, according to one or more example embodiments. The process of measuring the insertion layer is described with reference to FIGS. 4 and 5 in conjunction with FIGS. 1 to 3.

Referring to FIGS. 4 and 5, the insertion layer IL may be measured while disposed on the wafer W. FIG. 4 illustrates, as an example, a process of measuring a refractive index and an absorption coefficient of the insertion layer IL by using spectroscopic ellipsometry (SE).

A measurement device for determining the material of the insertion layer IL may include a spectroscopic ellipsometer. A spectroscopic ellipsometer may measure a semiconductor structure by using SE.

SE is an optical technique for investigating structural properties, such as the thickness of thin films and line widths of patterns formed on the thin films, and dielectric properties, such as a complex refractive index and a dielectric function. By using SE, the composition, roughness, thickness, depth, crystalline nature, doping concentration, electrical conductivity, etc. of thin films included in a sample to be inspected may be characterized.

SE is a technique for determining the properties of thin films by comparing a change in polarization before and after interaction with the thin films, such as reflection or transmission, to a model. Here, the polarization change may be represented by an amplitude ratio Ψ and a phase difference Δ. The amplitude ratio Ψ is a ratio of change in amplitudes of p-waves and s-waves when light is reflected from a thin film. The phase difference Δ refers to a phase change difference between p-waves and s-waves when light is reflected from the thin film. Because the polarization change depends on the type and thickness of a thin film material, the thickness and optical constants of all types of films may be measured in a non-contact manner. SE allows for characterization of single atomic layers, single layers, or multiple layers with thicknesses ranging from a few angstroms to a few micrometers with high precision.

Unpolarized electromagnetic radiation emitted by a light source may be linearly polarized by a polarizer. Optionally, a compensator, such as a retarder or quarter wave plate, may be further placed in the path of light between the polarizer and the sample.

The radiation reflected from the sample may pass through a second polarizer, often called an analyzer, before reaching the detector. Likewise, a second compensator may be placed in the path of light between the analyzer and the sample.

SE is a specular optical inspection method in which an angle of incidence equals an angle of reflection such that an incident beam and a reflected beam span the plane of incidence. Light polarized parallel to the plane of incidence is referred to as p-polarized light, and light polarized in a direction perpendicular to the p-polarized light is referred to as s-polarized light.

SE measures complex reflectance p, which may be parameterized by the amplitude ratio Ψ and the phase difference Δ upon reflection. The polarization state of light incident on the sample may be decomposed into an s component and a p component. The amplitudes of the s and p components after reflection, which are normalized to their initial values, are hereinafter denoted by rs and rp, respectively. In this case, rs, rp, and complex reflectance p satisfy Equation (1) below.

$$ρ = \frac{rp}{rs} = tan Ψ \cdot {e}^{i Δ} \qquad ( 1 )$$

By choosing the angle of incidence of light close to the Brewster angle of the sample, the difference between rp and rs may be maximized. Because SE measures a ratio (or difference) between two values, the method is capable of providing accurate and highly reproducible measurement results. Accordingly, SE has advantages of being relatively insensitive to light scattering and variations in inspection conditions and not requiring separate standard samples and reference beams.

Except for exceptionally simple cases such as infinitely thick films or homogeneous films, the measured amplitude ratio Ψ and phase difference Δ upon reflection may not be directly converted into optical constants of the sample. Therefore, in general, model analysis may be performed to obtain the optical constants from the results of SE. An example of a model is the Forouhi Bloomer model. A model may be based on physical energy transitions or free parameters for data fitting. The model may include a stacking order of layers in the sample, and the optical constants (e.g., refractive index or dielectric function tensor) and thickness parameters of the individual layers.

SE may determine the amplitude ratio Ψ and phase difference Δ upon reflection by using iterations (e.g., a least square method) for varying optical constants and/or thickness parameters. The Fresnel equations may be used to determine the amplitude ratio Y′ and phase difference Δ upon reflection. When the determined amplitude ratio Ψ and phase difference Δ match experimental data, optical constants and thickness parameters of thin films corresponding to the determined values may be determined as the optical constants and thickness parameters of the thin films in the sample.

Referring back to FIG. 1, after the material of the insertion layer IL is determined in operation S200, a thickness T of the insertion layer IL may be determined in operation S300. In order to determine the thickness T of the insertion layer IL, a simulation may be performed while varying the thickness T of the material of the insertion layer IL determined in operation S200. For example, the thickness T of the insertion layer IL when a signal-to-noise ratio (SNR) is highest may be determined as a final thickness of the insertion layer IL. In one or more embodiments, a wavelength of the measurement device may be selected based on an SNR.

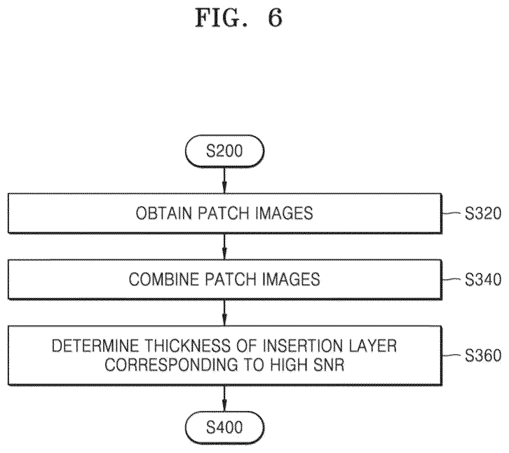

The method of determining the thickness T of the insertion layer IL is described in more detail with reference to FIGS. 6 to 9.

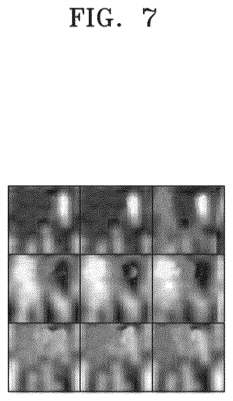

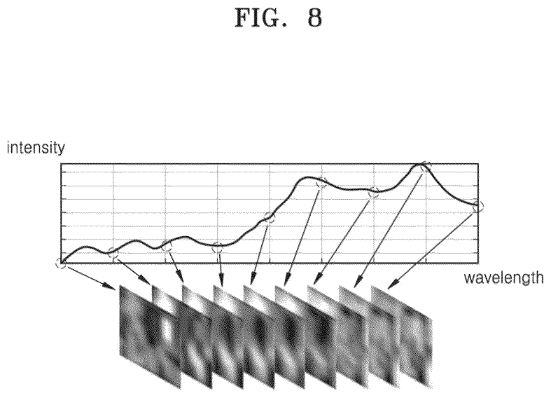

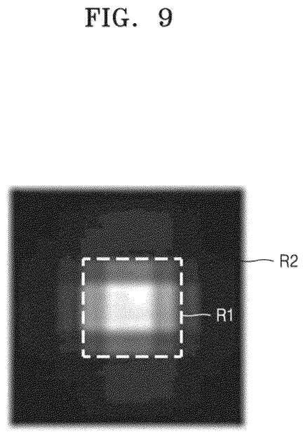

FIG. 6 is a flowchart illustrating a method of determining a thickness of an insertion layer, according to one or more example embodiments. FIG. 7 is a diagram illustrating patch images obtained at a plurality of wavelengths, according to one or more example embodiments. FIG. 8 is a diagram illustrating a method of combining a plurality of patch images, according to one or more example embodiments. FIG. 9 is a diagram illustrating a method of determining an SNR, according to one or more example embodiments. The method of determining the thickness of the insertion layer IL is described with reference to FIGS. 6 to 9 in conjunction with FIGS. 1 to 3.

Referring to FIGS. 6 to 9, in order to determine the thickness T of the insertion layer IL, first, a plurality of patch images may be obtained in operation S320. For example, FIG. 7 shows a plurality of patch images. The plurality of patch images may be obtained by performing a measurement simulation on the semiconductor structure including the insertion layer IL at various wavelengths. For example, each of the plurality of wavelengths may be spaced apart by about 5 nm from adjacent wavelengths. These are examples of values, and the disclosure is not limited thereto.

A plurality of patch images may be obtained by performing a measurement simulation on modeling of the semiconductor structure, which is obtained in operation S100. The measurement simulation may include a process of obtaining a plurality of patch images of the semiconductor structure by performing a simulation on the semiconductor structure with the insertion layer IL inserted therein. The measurement simulation may include a process of obtaining a plurality of patch images by measuring the semiconductor structure with the insertion layer IL inserted therein by using light. The measurement simulation may include a process of using the property that reflected light varies depending on the refractive index and absorption coefficient of the sample. The measurement simulation may include a process of obtaining a plurality of patch images by using light reflected from the sample. For example, a patch image may be represented in gray level scale.

Thereafter, the plurality of patch images of the semiconductor structure may be combined together in operation S340. As shown in FIG. 8, a final patch image of the semiconductor structure may be formed by combining the plurality of patch images obtained via the simulation at the plurality of wavelengths. For example, the plurality of patch images of a semiconductor structure obtained via the simulation at the plurality of wavelengths may be combined based on a weight of light intensity of each of the patch images. In other words, an image with high light intensity may have a high weight. The final patch image of the semiconductor structure may be generated by using Equation (2) below:

$${P}_{total} = {\sum }_{i = 1}^{n} {I}_{{λ}_{i}} {P}_{i} \qquad ( 2 )$$

where Pₜₒₜₐₗ represents the final patch image, I_{λ}_{ᵢ} represents light intensity at an i-th wavelength, Pᵢ represents a patch image at the i-th wavelength, and n represents the number of wavelengths used.

Thereafter, by varying the thickness T of the insertion layer IL, a thickness T of the insertion layer IL corresponding to a high SNR may be determined in operation S360.

To determine the thickness T of the insertion layer IL corresponding to a high SNR, a difference image, which is the difference between a defect image, which is a patch image of a combination of a captured image of an inspection pattern IP containing a defect, and a normal image, which is a patch image formed by capturing an inspection pattern IP not containing a defect, may be measured. FIG. 9 shows, as an example, a difference image.

The difference image of FIG. 9 may include a first region R1 with relatively high light intensity and a second region R2 with relatively low light intensity. The first region R1 may correspond to a region with a large difference in light intensity between a defect image and a normal image, and the second region R2 may correspond to a region with a small difference in light intensity between the defect image and the normal image. Thus, the defect may be located adjacent to the first region R1. In a plan view, the second region R2 may surround the first region R1. A maximum intensity of light in the first region R1 and a maximum intensity of light in the second region R2 may be determined. The maximum intensity of light in the first region R1 relative to the maximum intensity of light in the second region R2 may be determined as an SNR of a patch image.

An SNR of each of the combined final patch images obtained by varying the thickness T of the insertion layer may be determined. In this case, a thickness T of the insertion layer IL corresponding to a patch image with a highest SNR may be determined as a final thickness T of the insertion layer IL. Therefore, when measuring the semiconductor structure having the insertion layer IL of the determined final thickness T inserted, an SNR of the measurement result may be the highest. Therefore, the semiconductor structure may be measured with high reliability.

For example, the thickness T of the insertion layer IL may be in a range of about 1 nm to about 200 nm. In one or more embodiments, the insertion layer IL may be omitted.

Referring back to FIG. 1, after the thickness T of the insertion layer IL is determined in operation S300, the semiconductor structure may be measured with the insertion layer IL inserted therein in operation S400. As described above, the optical signal reflected from the semiconductor structure may be amplified by inserting the insertion layer IL therein, and thus, the measurement device may easily measure the semiconductor structure. In operation S400, an optical microscope may be used to measure the semiconductor structure. The optical microscope may be used to measure the semiconductor structure by using a plurality of wavelengths. For example, the optical microscope may measure the semiconductor structure by using a bright field. In other words, the measurement device may measure the semiconductor structure by using light reflected from the semiconductor structure.

Inspection equipment according to one or more embodiments of the disclosure may insert an insertion layer IL between an object to be inspected and a substrate such that an optical signal emitted from the object to be inspected may be amplified. Accordingly, the reliability of the inspection method may be increased. In addition, the reliability of the semiconductor structure inspection method may be increased by measuring the semiconductor structure under measurement conditions corresponding to a high SNR (e.g., a thickness T of the insertion layer IL, setup of the measurement device, etc.).

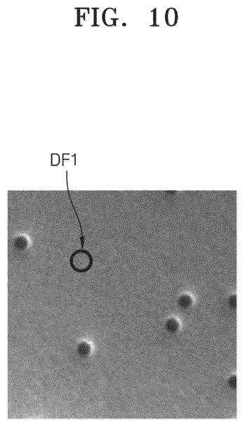

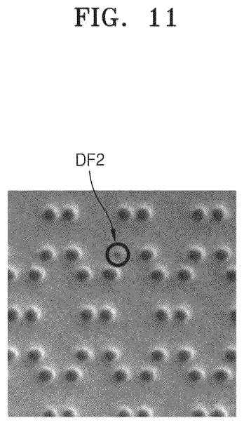

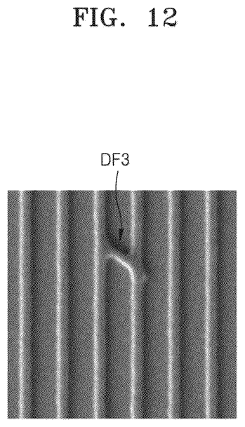

FIGS. 10 to 12 are diagrams illustrating scanning electrode microscope (SEM) images of semiconductor structures including defects, according to one or more example embodiments. FIGS. 10 and 11 show SEM images including contact defects, and FIG. 12 shows an SEM image including bridge defects.

Referring to FIGS. 10 and 11, contact defects may occur. FIGS. 10 and 11 each show that a contact defect is formed inside a circular shape. For example, contact defects may include contact missing and/or contact abnormality. A first defect DF1 may include contact missing, and a second defect DF2 may include contact abnormality. The contact missing (defect DF1) of FIG. 10 may refer to a case where a contact to be formed does not occur, and the contact abnormality (defect DF2) of FIG. 11 may refer to a case where the formed contact has a different dimension and/or shape than a normal contact. Contact defects may cause disconnection of electrical signals and/or reduced yield of semiconductor devices.

Referring to FIG. 12, a bridge defect may occur in a pattern. A third defect DF3 may include a bridge defect and/or a cut defect. For example, a bridge defect (defect DF3) may occur between line patterns that are spaced apart from each other. A bridge defect may indicate that a plurality of line patterns that should be separated from each other are connected to each other. A cut defect may indicate that a plurality of line patterns that should be connected to each other are spaced apart from each other. The bridge defect and the cut defect may cause shorts in electrical signals, interference of electrical signals, and/or reduced yield of semiconductor devices.

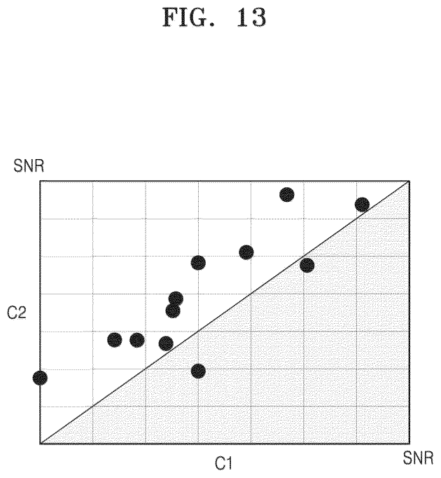

FIG. 13 is a graph illustrating an SNR in a first condition and an SNR in a second condition, according to one or more example embodiments.

In FIG. 13, the horizontal axis represents an SNR in a first condition C1 and the vertical axis represents an SNR in a second condition C2. For the same pattern to be inspected and inspection wavelength, the SNR measured in the first condition C1 and the SNR measured in the second condition C2 are shown. Conditions may vary depending on factors (e.g., material and thickness T of the insertion layer IL, setup of the measurement device, etc.) that may change a result of measurement of the semiconductor structure. That is, the conditions may vary depending on the material and thickness T of the insertion layer IL. The description of FIG. 13 is provided in conjunction with FIGS. 1 to 9. In FIG. 13, for example, the description is provided considering only the thickness T of the insertion layer IL.

Referring to FIG. 13, overall, the SNR measured in the second condition C2 may be higher than the SNR measured in the first condition C1. That is, results obtained via the measurement in the second condition C2 may have higher reliability than results obtained via the measurement in the first condition C1. Therefore, when measuring the semiconductor structure with the insertion layer IL having the second condition C2, the semiconductor structure may be measured with higher reliability than when measuring the semiconductor structure with the insertion layer IL having the first condition C1.

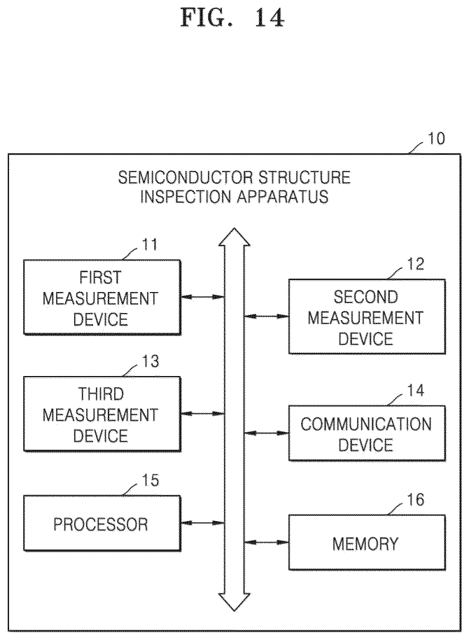

FIG. 14 is a block diagram illustrating a semiconductor structure inspection apparatus according to one or more example embodiments. A semiconductor structure inspection apparatus 10 is described with reference to FIG. 14 in conjunction with FIGS. 1 to 9.

Referring to FIG. 14, the semiconductor structure inspection apparatus 10 may include a first measurement device 11, a second measurement device 12, a third measurement device 13, a communication device 14, a processor 15, and a memory 16. However, components included in the semiconductor structure inspection apparatus 10 are not necessarily limited to the components described above, and the semiconductor structure inspection apparatus 10 may include various other components for inspecting the semiconductor structure.

The first measurement device 11 may measure the first semiconductor structure SS1. For example, the first measurement device 11 may include a TEM. The second measurement device 12 may measure the insertion layer IL. For example, the second measurement device 12 may measure the insertion layer IL while the insertion layer IL is disposed on the wafer W. For example, the second measurement device 12 may include a spectroscopic ellipsometer. The third measurement device 13 may measure the second semiconductor structure SS2. For example, the third measurement device 13 may include an optical microscope.

The communication device 14 may provide communication across a network to the semiconductor structure inspection apparatus 10. The network may be a wired network and/or a wireless network, such as a radio network, a cellular network, a satellite network, broadcasting, etc. In an embodiment, the semiconductor structure inspection apparatus 10 may be an electrical device with an image processing program installed, such as a computer, a smartphone, a personal computer, a server, or the like.

The processor 15 may model the first semiconductor structure SS1 measured by the first measurement device 11. The processor 15 may model the first semiconductor structure SS1, based on measurement results from the first measurement device 11 and data stored in the memory 16. The processor 15 may measure a refractive index and an absorption coefficient of the insertion layer IL based on data regarding the insertion layer IL measured by the second measurement device 12. The processor 15 may determine an optimal material for the insertion layer IL, based on the refractive index and absorption coefficient of the insertion layer IL. The processor 15 may combine patch images and determine optimal process inspection conditions. The processor 15 may determine whether the semiconductor structure is normal or defective based on measurement results from the third measurement device 13.

For example, the processor 15 may include a central processing unit (CPU), a graphics processing unit (GPU), a vector processor, a quantum processor, an embedded processor, etc. For example, the memory 16 may include flash memory, a hard disk drive (HDD), a solid state drive (SSD), dynamic random access memory (RAM) (DRAM), static RAM (SRAM), etc.

An apparatus and method for inspecting an EUV mask by measuring a photoresist pattern on a semiconductor structure is described in detail below. As described below, the inspection pattern IP may include a photoresist pattern. Furthermore, a system SYS as described below may inspect the photoresist pattern for defects to inspect an EUV mask for defects.

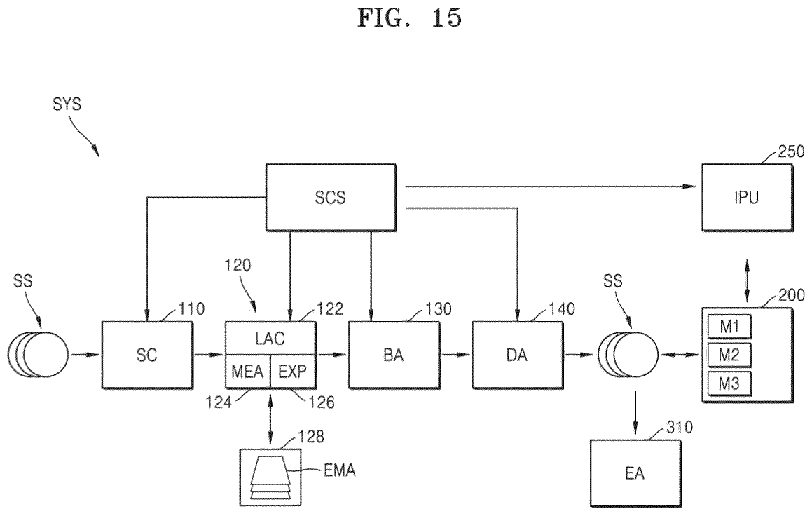

FIG. 15 is a block diagram illustrating a system for performing various processes according to one or more example embodiments.

Referring to FIG. 15, a system SYS may include a supervisory control system SCS, a spin coater 110 (“SC” in FIG. 15), a lithography apparatus 120, a baking apparatus 130 (“BA” in FIG. 15), a developing apparatus 140 (“DA” in FIG. 15), an inspection apparatus 200, and an etching apparatus 310 (“EA” in FIG. 15).

Processes performed by the system SYS may include fabrication of a wafer W or a semiconductor structure SS having a circuit structure implemented on the wafer W. The processes by the system SYS may include, in particular, a semiconductor fabrication process using EUV light. The semiconductor structure SS provided in the system SYS may include the wafer W and at least one semiconductor layer SL disposed on the wafer W.

The supervisory control system SCS may control each component included in the system SYS and all processes, and monitor results of the processes.

The spin coater 110 may provide a photoresist layer on the semiconductor structure SS by using spin coating.

The lithography apparatus 120 may perform an EUV lithography process. The lithography apparatus 120 may include a lithography apparatus controller 122 (“LAC” in FIG. 15), a measurement station 124 (“MEA” in FIG. 15), and an exposure station 126 (“EXP” in FIG. 15).

The lithography apparatus controller 122 may control the measurement station 124 and the exposure station 126 according to commands received from the supervisory control system SCS. The lithography apparatus controller 122 may control operations of various actuators and sensors to enable the lithography apparatus 120 to receive a semiconductor structure SS and an EUV mask EMA and perform a lithography operation on the semiconductor structure SS. The lithography apparatus controller 122 may have signal and data processing capacity to perform desired computations related to an operation of the lithography apparatus 120. The lithography apparatus controller 122 may be implemented by subsystems, such as multi-layer subsystems that handle real-time data collection, processing, and control of components.

The measurement station 124 may perform measurements on the semiconductor structure SS before exposure is performed. The measurement station 124 may map a surface height of the semiconductor structure SS and measure positions of alignment marks on the semiconductor structure SS. The alignment marks may have, for example, a box-in-box structure or a diffraction grating structure.

The lithography apparatus 120 may be a dual-stage type lithography apparatus including two wafer tables. The two wafer tables may be respectively provided for the measurement station 124 and the exposure station 126. Accordingly, while a semiconductor structure SS on one wafer table is being exposed, pre-exposure measurements may be performed on a semiconductor structure SS on the other wafer table. Because measurement of alignment marks takes a long time and the lithography process is the bottleneck in the entire semiconductor fabrication process, the throughput of semiconductor structures SS may be greatly improved by providing two wafer tables. However, the disclosure is not limited thereto, and the lithography apparatus 120 may be a mono-stage type lithography apparatus including a single wafer table.

The pre-exposure measurement of the semiconductor structure SS may include, for example, identifying positions of alignment marks included in patterns formed on the semiconductor structure SS. The lithography apparatus controller 122 may generate, based on the identified positions of the alignment marks, model functions representing identified positions of arbitrary patterns formed on the semiconductor structure SS. The lithography apparatus controller 122 may control the exposure station 126 to perform exposure on the semiconductor structure SS based on the model functions.

The exposure station 126 may include a projection system. The projection system may be a system for conditioning and focusing light for exposure. The projection system may include any type of projection system, including refractive, reflective, catadioptric, magnetic, electromagnetic, and electrostatic optical projection systems, and combinations thereof.

The mask library 128 may include a plurality of EUV masks EMA. An EUV mask EMA may be retrieved from a mask library 128 and mounted on a mask table within the exposure station 126. The EUV mask EMA may be moved by the mask table. An EUV beam may be focused onto the EUV mask EMA by the projection system. Light reflected by the EUV mask EMA may reach the semiconductor structure SS coated with a photoresist layer. Accordingly, a pattern on the EUV mask EMA may be transferred to the photoresist layer formed on the semiconductor structure SS.

The EUV mask EMA may be a mask or a reticle and impart a pattern to a radiation beam reflected by the EUV mask EMA. Modes of exposure to a radiation beam passing through the EUV mask EMA include a stepping mode and a scanning mode. The radiation beam may be, for example, radiation in an EUV wavelength band.

The semiconductor structure SS may include appropriate materials and patterns, layer by layer, on the wafer W. The semiconductor structure SS that arrives at the lithography apparatus 120 may be a newly prepared substrate, or a semiconductor structure SS that has previously been processed in the lithography apparatus 120 or another apparatus. The semiconductor structure SS that is unloaded from the lithography apparatus 120 may be reloaded for additional exposure in the lithography apparatus 120, subjected to patterning by the developing apparatus 140 or the like, or finished using dicing and packaging processes, etc.

The baking apparatus 130 may perform post-exposure bake or pre-exposure bake on the photoresist layer. The semiconductor structure SS may be transferred to the developing apparatus 140 without performing a bake process by the baking apparatus 130.

The developing apparatus 140 may develop the exposed photoresist layer to form a photoresist pattern.

To improve the accuracy and consistency of the exposure process by the lithography apparatus 120, inspection of the exposed semiconductor structure SS may be performed. The inspection of the semiconductor structure SS may be, but is not limited to, image-based inspection such as bright field image-based inspection. Inspection of the semiconductor structure SS may further include measurements of overlay between layers, line widths, critical dimensions, etc.

The system SYS may include the inspection apparatus 200 for performing such measurements. Results of inspection by the inspection apparatus 200, such as measurement results, may be provided directly or indirectly to the supervisory control system SCS. When an error in the exposure process is detected, an EUV lithography process may be adjusted for other wafers in the same batch or subsequent semiconductor structures SS. Already exposed semiconductor structures SS may be reprocessed after stripping the photoresist pattern to improve yield. In some cases, a semiconductor structure SS determined to have an irreparable defect may be discarded. When only some regions of a semiconductor structure SS are defective, additional processes may be performed only on normal regions thereof.

The inspection apparatus 200 may include a plurality of measurement devices, such as first to third measurement devices M1, M2, and M3. However, the inspection apparatus 200 may include two or less measurement devices and/or four or more measurement devices. The first measurement device M1 may measure a semiconductor structure SS without the insertion layer IL, the second measurement device M2 may measure the insertion layer IL, and the third measurement device M3 may measure a semiconductor structure SS with the insertion layer IL inserted therein.

The inspection apparatus 200 may measure properties of the semiconductor structure SS subjected to a development process before an etching process is performed.

The first measurement device M1 may include a TEM, the second measurement device M2 may include a spectroscopic ellipsometer, and the third measurement device M3 may include an optical microscope.

The inspection apparatus 200 may be used to measure the properties of the semiconductor structure SS after the development process is performed and before the etching process is performed. The first to third measurement devices M1, M2, and M3 may each be any of the measurement devices described with respect to FIGS. 1 to 9.

An inspection controller 250 (“IPU” in FIG. 15) may receive commands from the supervisory control system SCS and control the inspection apparatus 200 to perform predetermined inspections. According to one or more embodiments, the inspection controller 250 may control the inspection apparatus 200 to obtain a scattering image of the semiconductor structure SS.

The inspection controller 250 may model an image of the photoresist pattern based on measurement results from the first measurement device M1. Furthermore, the inspection controller 250 may measure the refractive index and absorption coefficient of the insertion layer IL based on measurement results from the second measurement device M2. The inspection controller 250 may obtain a plurality of patch images by performing simulation of the semiconductor device SS having the insertion layer IL of various thicknesses T. The inspection controller 250 may determine a final patch image by combining the plurality of patch images obtained at various wavelengths based on their light intensity. The inspection controller 250 may determine an optimal thickness T of the insertion layer IL by determining an SNR of each final patch image. The inspection controller 250 may control the third measurement device M3 to measure the semiconductor device SS with the insertion layer IL inserted therein. The inspection controller 250 may inspect the photoresist pattern for defects, based on measurement results from the third measurement device M3. The inspection controller 250 may inspect the EUV mask EMA for defects, based on the detected defects in the photoresist pattern.

According to one or more embodiments, the inspection controller 250 may be implemented in hardware, firmware, software, or any combination thereof. According to one or more embodiments, operations of the inspection controller 250 may be implemented as commands stored on machine-readable media, which are readable or executable by one or more processors. In this case, the machine-readable media may include any mechanism for storing and/or transmitting information in a form readable by a machine (e.g., a computing device). For example, the machine-readable media may include read-only memory (ROM), RAM, magnetic disk storage media, optical storage media, flash memory devices, electrical, optical, acoustical or other types of radio signals (e.g. carrier waves, infrared signals, digital signals, etc.), and any other signals. Furthermore, firmware, software, routines, and instructions may be configured to perform the operations described with respect to the inspection controller 250, or any process as described below. However, it should be appreciated that this is merely for convenience of description and that the operations of the inspection controller 250 may be caused by a computing device, a processor, a controller, or other devices executing the firmware, software, routines, instructions, etc.

The system SYS may further include, for example, the etching apparatus 310. The etching apparatus 310 may etch the semiconductor structure SS by using the developed photoresist pattern as an etch mask.

According to other embodiments, the system SYS may further include devices for performing an ion implantation process, a deposition process, etc.

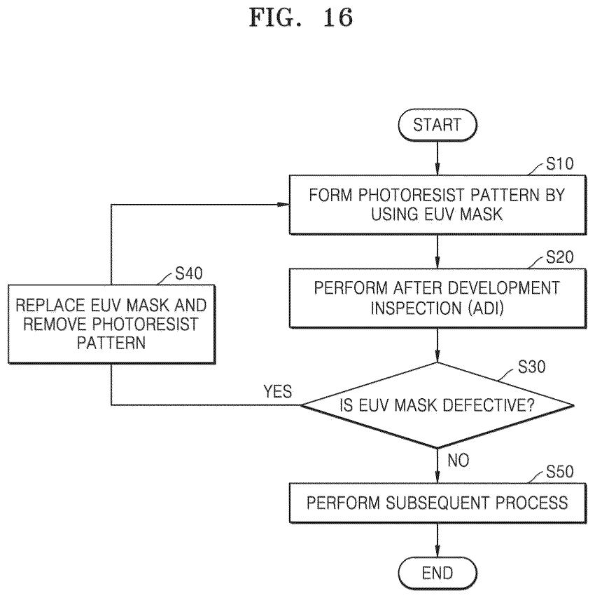

FIG. 16 is a flowchart illustrating an EUV lithography method according to one or more example embodiments. The EUV lithography method is described with reference to FIG. 16 in conjunction with FIGS. 1 to 9 and 15

Each of the hundreds of processes included in a semiconductor manufacturing process affects the yield and performance of a final product, and in particular, an exposure process that forms fine patterns is a key factor that determines the yield in the semiconductor manufacturing process. Recently, as the use of EUV processes has expanded to various product lines, the quality impact of defects occurring in an EUV mask, such as an EUV pellicle, used during exposure has increased.

A method of inspecting an EUV mask may include, in addition to directly inspecting the EUV mask itself, inspecting a photoresist pattern after performing exposure and development processes using the EUV mask as a patterning mask and before performing an etching process. A technique for inspecting the developed photoresist pattern may be referred to as after development inspection (ADI). This ADI inspection method may use one or more optical systems to measure properties of a semiconductor structure SS being inspected.

Referring to FIG. 16, first, a photoresist pattern may be formed using an EUV mask in operation S10. Forming the photoresist pattern may include sequentially performing spin coating, exposure, and development, as described with reference to FIG. 15.

Thereafter, an ADI may be performed in operation S20. The ADI in operation S20 may include obtaining an image of a semiconductor structure (operation S100 of FIG. 1), determining a material of an insertion layer IL (operation S200 of FIG. 1), determining a thickness of the insertion layer IL (operation S300 of FIG. 1), and measuring the semiconductor structure (operation S400 of FIG. 1). That is, the ADI may be performed by inspecting the photoresist pattern on the semiconductor structure SS.

Thereafter, it may be determined whether a defect occurs in the EUV mask in operation S30. The presence of a defect in the EUV mask may be determined by whether a defect occurs in the photoresist pattern.

Types of EUV mask defects may include intrusion, protrusion, mouse bite, bridge, cut, necking, and pinching. Because the presence of a mask defect is determined based on whether a defect occurs in the photoresist pattern, the accuracy of predicting whether a mask defect will occur may be improved.

When the EUV mask is determined to be defective (YES in operation S30), the EUV mask may be replaced, and the photoresist pattern may be removed in operation S40. After removing the photoresist pattern, the process may return to operation S10.

When the EUV mask is determined not to be defective (NO in operation S30), a subsequent process may be performed in operation S50. Subsequent processes may include various processes, such as an etching process using the photoresist pattern as an etch mask, an ion implantation process, a deposition process, etc.

As used in connection with various embodiments of the disclosure, the term “module” may include a unit implemented in hardware, software, or firmware, and may interchangeably be used with other terms, for example, logic, logic block, part, or circuitry. A module may be a single integral component, or a minimum unit or part thereof, adapted to perform one or more functions. For example, according to one or more embodiments, the module may be implemented in a form of an application-specific integrated circuit (ASIC).

Various embodiments as set forth herein may be implemented as software including one or more instructions that are stored in a storage medium that is readable by a machine. For example, a processor of the machine may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to one or more embodiments, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

At least one of the devices, units, components, modules, units, or the like represented by a block or an equivalent indication in the above embodiments including, but not limited to, FIGS. 14 and 15, may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein).

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor structure inspection method comprising:
obtaining an image of a semiconductor structure, the semiconductor structure comprising a wafer, a semiconductor layer, and an inspection pattern;
determining a material of an insertion layer to be inserted in the semiconductor structure;
determining a thickness of the insertion layer;
inserting the insertion layer having the determined material and the determined thickness in the semiconductor structure; and
measuring the semiconductor structure having the insertion layer inserted therein.

2. The semiconductor structure inspection method of claim 1, wherein the obtaining of the image of the semiconductor structure comprises measuring the inspection pattern.

3. The semiconductor structure inspection method of claim 1, wherein the determining of the material of the insertion layer comprises determining the material of the insertion layer based on a refractive index and an absorption coefficient of the insertion layer.

4. The semiconductor structure inspection method of claim 1, wherein the determining of the thickness of the insertion layer comprises:
obtaining a plurality of patch images at a plurality of wavelengths;
combining the plurality of patch images; and
determining a signal-to-noise ratio (SNR) corresponding to the combined plurality of patch images.

5. The semiconductor structure inspection method of claim 4, wherein the combining of the plurality of patch images comprises combining the obtained plurality of patch images by assigning weights to the respective light intensities of the plurality of patch images.

6. The semiconductor structure inspection method of claim 4, wherein the determining of the SNR is performed by:
dividing a difference image into a first region having a first difference in light intensity and a second region having a second difference in light intensity that is less than the first difference in light intensity; and
comparing a value of light intensity of the first region relative to a value of light intensity of the second region,
wherein the difference image is an image corresponding to a difference between a defect image and a normal image,
wherein the defect image is a combined patch image comprising at least one defect, and
wherein the normal image is a combined patch image that does not comprise a defect.

7. The semiconductor structure inspection method of claim 1, wherein a wavelength band for measuring the semiconductor structure is selected based on a location corresponding to a placement of the inspection pattern, a size of the inspection pattern, and a surrounding material adjacent to the inspection pattern.

8. An extreme ultraviolet (EUV) mask inspection method comprising:
forming a photoresist layer on a wafer and a semiconductor layer of a semiconductor structure;
forming a photoresist pattern by exposing the photoresist layer using an EUV mask;
obtaining an image of the photoresist pattern;
determining a material of an insertion layer to be inserted in the semiconductor structure;
determining a thickness of the insertion layer;
inserting the insertion layer in the semiconductor structure; and
determining whether the EUV mask is defective by measuring the photoresist pattern with the insertion layer having the determined material and the determined thickness inserted in the semiconductor structure.

9. The EUV mask inspection method of claim 8, wherein the obtaining of the image of the photoresist pattern comprises measuring dimensions of the photoresist pattern.

10. The EUV mask inspection method of claim 8, wherein the determining of the material of the insertion layer is performed by measuring, by a measurement device, the insertion layer while the insertion layer is inserted in the semiconductor structure.

11. The EUV mask inspection method of claim 8, wherein the determining of the thickness of the insertion layer comprises obtaining a plurality of patch images by performing a simulation for a plurality of wavelengths, with the insertion layer inserted between the wafer and the photoresist pattern.

12. The EUV mask inspection method of claim 8, wherein the determining of the thickness of the insertion layer comprises:
combining the plurality of patch images; and
determining a signal-to-noise ratio (SNR) of each of combined patch images,
wherein the determining of the SNR is performed by:
dividing a difference image into a first region having a first difference in light intensity and a second region having a second difference in light intensity that is less than the first difference in light intensity; and
comparing, for each of the combined patch images, a maximum light intensity of the first region to a maximum light intensity of the second region, and
wherein the difference image is an image corresponding to a difference between a defect image and a normal image,
wherein the defect image is a combined patch image comprising at least one defect, and
wherein the normal image is a combined patch image that does not comprise a defect.

13. The EUV mask inspection method of claim 8, wherein the insertion layer comprises at least one of silicon nitride (SiN), silicon oxynitride (SiON), titanium nitride (TiN), tungsten (W), gold (Au), photoresist PR, silicon oxycarbide (SiOC), and silicon carbide (SiC).

14. The EUV mask inspection method of claim 8, wherein the insertion layer is between the semiconductor layer and the photoresist pattern.

15. The EUV mask inspection method of claim 8, wherein the thickness of the insertion layer is in a range of about 1 nanometer (nm) to about 200 nm.

16. The EUV mask inspection method of claim 8, wherein the obtaining of the image of the photoresist pattern is performed by a transmission electron microscope (TEM),
wherein the determining of the material of the insertion layer is performed by a spectroscopic ellipsometer, and
wherein the measuring of the photoresist pattern with the insertion layer inserted in the semiconductor structure is performed by an optical microscope.

17. An extreme ultraviolet (EUV) lithography method comprising:
providing a semiconductor layer on a wafer;
providing a photoresist layer on the wafer;
exposing the photoresist layer on the wafer using an EUV mask;
forming a photoresist pattern by developing the exposed photoresist layer; and
determining whether the EUV mask is defective by inspecting the photoresist pattern,
wherein the inspecting of the photoresist pattern comprises:
obtaining an image of the photoresist pattern;
determining a material of an insertion layer to be inserted in a semiconductor structure, the semiconductor structure comprising the semiconductor layer, the wafer, and the photoresist layer;
determining a thickness of the insertion layer;
inserting the insertion layer having the determined material and the determined thickness into the semiconductor structure; and
measuring the photoresist pattern while the insertion layer is inserted in the semiconductor structure.

18. The EUV lithography method of claim 17, wherein the material of the insertion layer is determined based on a refractive index and an absorption coefficient of the insertion layer, and
wherein the thickness of the insertion layer is determined based on a signal-to-noise ratio (SNR).

19. The EUV lithography method of claim 17, further comprising, when the EUV mask is determined to be defective, removing the photoresist pattern.

20. The EUV lithography method of claim 17, further comprising, when the EUV mask is determined not to be defective, etching the semiconductor layer using the photoresist pattern.
